(19) United States
(12) Patent Application Publication
(10) Pub. No.: US 2005/0257104 A1
(43) Pub. Date: Nov. 17, 2005

(54) Method and apparatus for bit error rate test

(76) Inventor: Reed Glenn Wood JR., Colorado Springs, CO (US)

Correspondence Address: AGILENT TECHNOLOGIES, INC.;Legal Department, DL429, Intellectual Property Administration, P.O. Box 7599, Loveland, CO, 80537-0599, US

(21) Appl. No.: 10/846,469

(22) Filed: May 14, 2004

(51) Int. Cl. G06F 11/00; G01R 31/28

(52) U.S. Cl. 714/704

(57) ABSTRACT

A method and apparatus for measuring a bit error rate of a system. A sequencer circuit is programmed to recognize at least one predefined invalid bit pattern. An expected bit pattern is stored, and a bit pattern is received from the device. After the sequencer detects a start of data pattern in the incoming signal and while the sequencer circuit recognizes the received bit pattern as valid, the received bit pattern is compared against the expected bit pattern. A bit error rate is computed based on the number of compared bits and the number of error bits, wherein error bits are bit pattern bits that differ from corresponding bits in the expected bit pattern.

### BACKGROUND

In modern digital systems, signals are not always propagated error free. Signal errors may be due to a variety of causes including noise, signal distortion, signal misalignment, and the like. Thus, a fundamental and important measure of system performance is the rate at which errors occur. In a digital system, this measure of system performance is the bit error rate. The bit error rate is the number of bits in a data stream that are in error divided by the total number of bits in the data stream. The bit error rate is essentially a measure of how accurately bits are transferred through a system and describes by means of a single number the ability of the system to propagate information error-free. This parameter is a commonly used measure of the quality of a device, network, or other system.

Common bit error rate testers (BERT's) have the ability to propagate patterns into a device under test (DUT). The bit error rate tester then receives back the same signal with the exception of those bits in which an error has occurred. The received signal is compared to the transmitted signal in order to determine which of the returned bits are in error. As indicated above, the number of bit errors and the total number of bits compared are separately added prior to computing a bit error rate. This type of test is referred to as a loopback test.

Other bit error rate testers permit the device under test to generate a test pattern and then transmit that generated test pattern to the bit error rate tester. For such tests, the bit error rate tester must be programmed as to the generated test pattern which it expects to receive from the device under test. This type of test is referred to as a half-loopback test.

In either case, the result is a bit error rate for the system, whether the system is a stand alone device, a communication link, another electronic device, or another electronic system. For communication links, the bit error rate is a widely accepted measure of the robustness of the links with most current specifications calling for bit error rates in the range of 1E-10 to 1E-12.

### SUMMARY

In representative embodiments, techniques for measuring a bit error rate of a system are disclosed. In one representative embodiment, a sequencer circuit is programmed to recognize at least one predefined invalid bit pattern. An expected bit pattern is stored, and a bit pattern is received from the device. After the sequencer detects a start of data pattern in the incoming signal and while the sequencer circuit recognizes the received bit pattern as valid, the received bit pattern is compared against the expected bit pattern. A bit error rate is computed based on the number of compared bits and the number of error bits, wherein error bits are bit pattern bits that differ from corresponding bits in the expected bit pattern.

In another representative embodiment, an instrument for measuring a bit error rate of a device comprises a sequencer circuit, a memory, a digital comparator, and a bit error rate calculator. The sequencer circuit is capable of receiving a bit pattern from the device and modifying the received bit pattern by removing bit patterns previously identified to the sequencer as invalid. The memory is capable of storing an expected bit pattern. The digital comparator has a first input, a second input, and an output. The first input of the digital comparator is connected to an output of the sequencer circuit and is capable of receiving bit pattern as modified by the sequencer. The second input of the digital comparator is connected to the memory and is capable of receiving the stored expected bit pattern. And the output of the digital comparator is capable of receiving result of a comparison of bit pattern applied to the first input with bit pattern applied to the second input. The bit error rate calculator has input connected to the output of the digital comparator and has capability of calculating a bit error rate.

Other aspects and advantages of the representative embodiments presented herein will become apparent from the following detailed description, taken in conjunction with the accompanying drawings.

### BRIEF DESCRIPTION OF THE DRAWINGS

The accompanying drawings provide visual representations which will be used to more fully describe various representative embodiments and can be used by those skilled in the art to better understand them and their inherent advantages. In these drawings, like reference numerals identify corresponding elements.

FIG. 1A is a block diagram of a system for measuring a bit error rate of a device under test (DUT) as described in various representative embodiments.

FIG. 1B is a block diagram of another system for measuring the bit error rate of the device under test as described in various representative embodiments.

FIG. 2A is a block diagram of a representative bit pattern as used in the measurement of bit error rate in the systems of FIGS. 1A-1B.

FIG. 2B is a block diagram of another representative bit pattern as used in the measurement of bit error rate in the systems of FIGS. 1A-1B.

FIG. 2C is a block diagram of still another representative bit pattern as used in the measurement of bit error rate in the systems of FIGS. 1A-1B.

FIG. 2D is a block diagram of yet other representative bit pattern as used in the measurement of bit error rate in the systems of FIGS. 1A-1B.

FIG. 3 is a flow chart of a method for measuring the bit error rate of the device under test as described in various representative embodiments.

FIG. 4 is a flow chart of another method for measuring the bit error rate of the device under test as described in various representative embodiments.

### DETAILED DESCRIPTION

As shown in the drawings for purposes of illustration, the present patent document discloses novel techniques for the measurement of bit error rates in digital electronic systems. Previous techniques often do not provide an accurate representation of the bit error rate for those systems in which the pattern is dynamic. Some such systems provide for the insertion of various patterns into the returned data stream. For example, serial busses may permit the dynamic insertion of idle states in order to keep their communication links open. Plesiochronous systems may permit the dynamic insertion of dummy patterns to allow for skips and/or insertions of bits and symbols. Even parallel busses may have dynamic data mixed in with a static data pattern. When the bit pattern being used as a test signal changes in previous bit error testers, the bit error testers typically will lose synchronization and will report, thereby, a falsely high bit error rate. This potential situation will often force the user to employ a static pattern mode for the device under test in order to obtain a more reasonable measure of the bit error rate. However, this situation is often either impossible or undesirable.

A static datastream is one in which the expected data sequence has no unknowns in it. It is a fixed length sequence in which every bit is defined ahead of time. This is the type of datastream that previous bit error rate testers need in order to obtain an accurate error rate. Previous bit rate testers in full-loopback mode transmit a static datastream into the device under test and then look for its return from the device under test. Previous error rate testers in half-loopback mode expect the static data stream to be programmed into their pattern memory and they expect the device under test to be placed in a mode in which it transmits, often repeatedly, this static datastream.

In the following detailed description and in the several figures of the drawings, like elements are identified with like reference numerals.

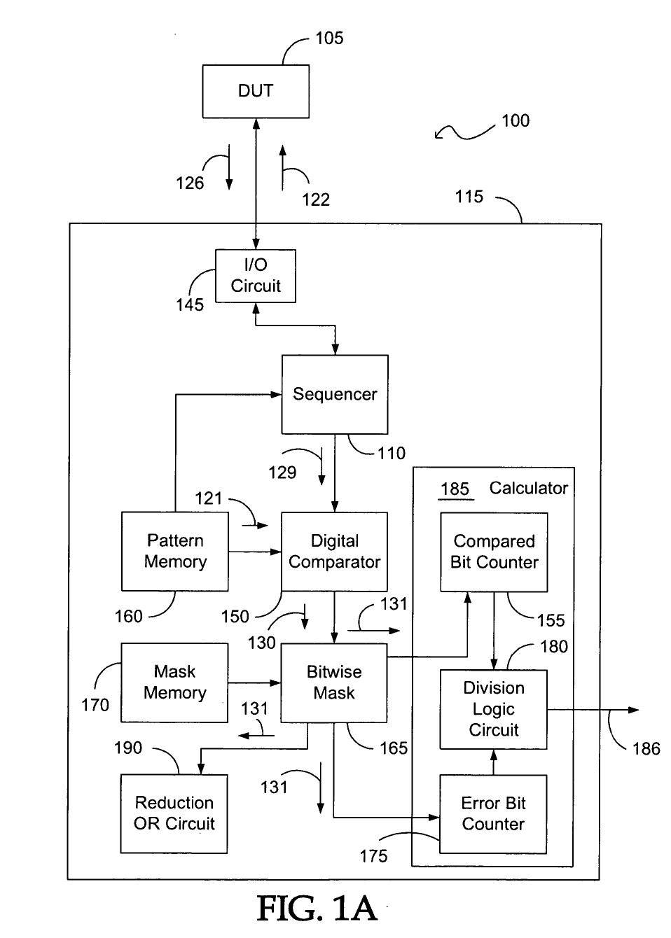

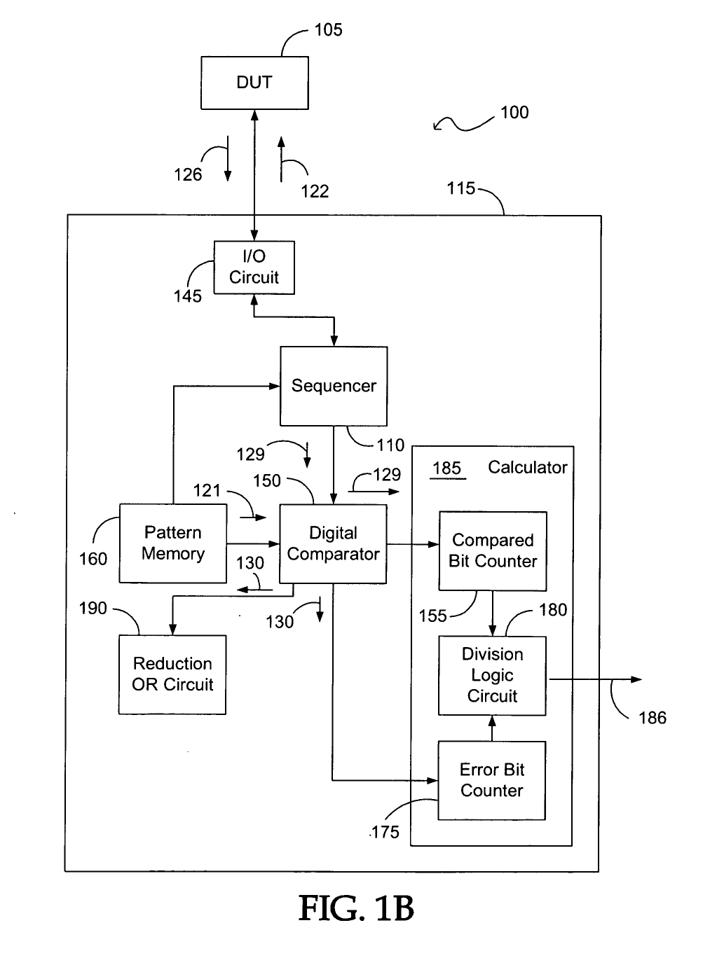

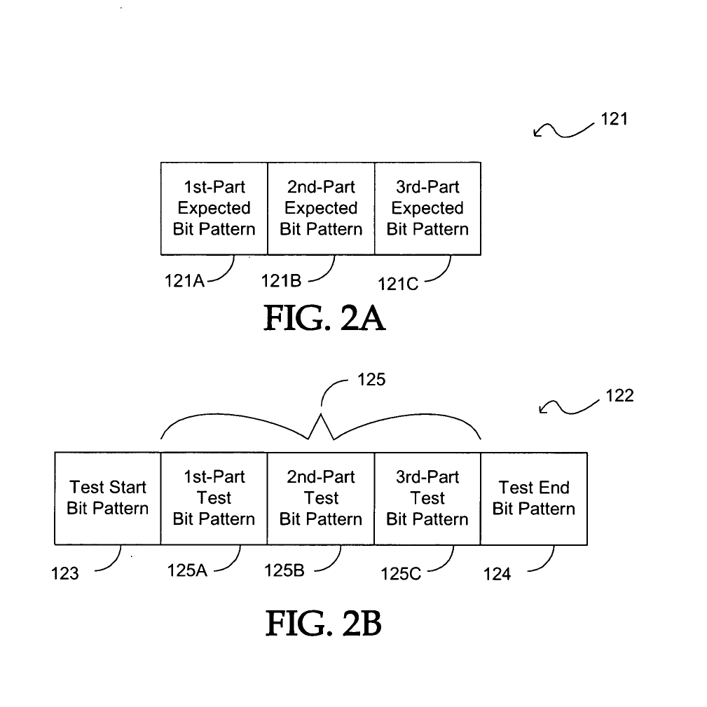

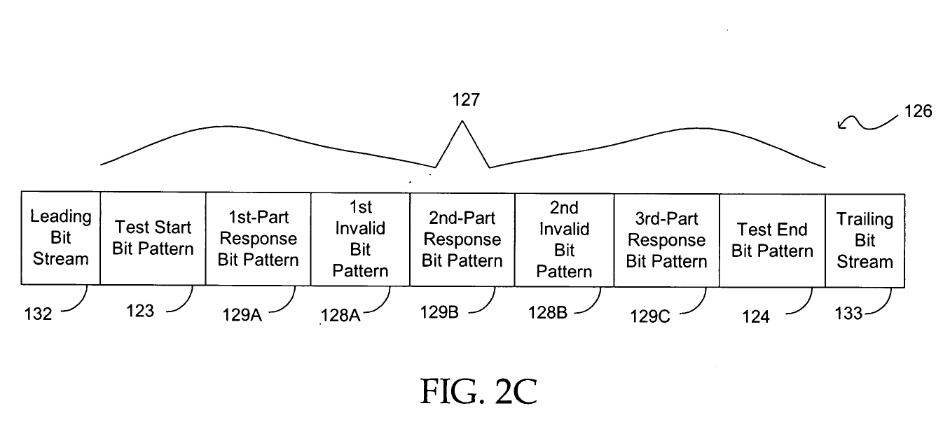

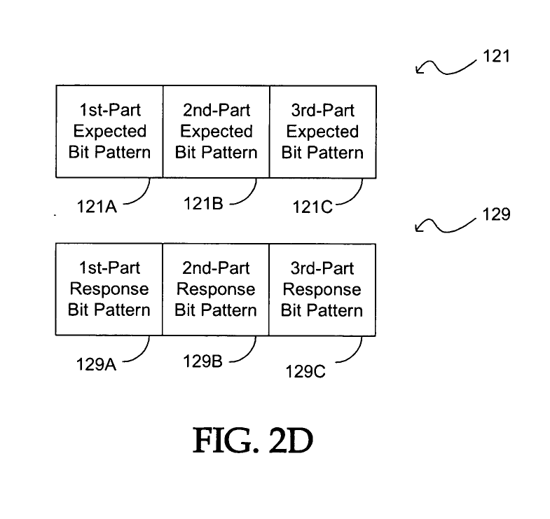

FIG. 1A is a block diagram of a system 100 for measuring a bit error rate of a device under test (DUT) 105 as described in various representative embodiments. In FIG. 1A, a sequencer 110, also referred to herein as a sequencer circuit 110, in a test instrument 115 obtains at least part of a transmitted bit pattern 122 from a pattern memory 160, also referred to herein as a pattern memory circuit 160, and transmits the transmitted bit pattern 122 to the device under test 105 via an Input/Output (I/O) circuit 145. The test instrument 115 via I/O circuit 145 receives back a received bit pattern 126 from the device under test 105 which, in response to the transmitted bit pattern 122 comprises a return bit pattern 127 (see FIG. 2C and related discussion). After removing any invalid bit patterns 128 (see first invalid bit pattern 128A second invalid bit pattern 128B in FIG. 2C with related discussion) and any beginning and end of test indicators from the return bit pattern 127, the sequencer 110 passes the resultant bit pattern as a response bit pattern 129 (see first-part response bit pattern 129A, second-part response bit pattern 129B, and third-part response bit pattern 129C in FIGS. 2C-2D with related discussion) to a digital comparator 150, also referred to herein as a digital comparator circuit 150.

The sequencer 110 is basically a programmable state machine with a fixed number of states resulting in a fixed set of outputs from a fixed set of inputs (i.e. various pattern detects on the bus). The outputs of the sequencer 110 are functions of logical combinations of pattern detects on the currently received bus sample or on a history of the pattern detects on the current and prior bus samples.

The digital comparator 150 obtains an expected bit pattern 121 from the pattern memory 160 and compares the response bit pattern 129 to the expected bit pattern 121. The digital comparator 150 identifies those bits in the response bit pattern 129 that differ from their respective bits in the expected bit pattern 121 and then passes the result of that comparison to a bitwise mask 165, also referred to herein as a bitwise mask circuit 165. The result of the comparison identification is error bit pattern 130.

A mask pattern obtained from a mask memory 170 provides mask input to the bitwise mask 165 whose output is a masked error bit pattern 131. The bitwise mask 165 transfers the masked error bit pattern 131 to an error bit counter 175 which from the identification of error bits in the masked error bit pattern 131 counts those bits in the response bit pattern 129 that, after the masking of the bitwise mask 165, differ from their respective bits in the expected bit pattern 121. The error bit counter 175 transfers the count of those bits in the response bit pattern 129 that, after the masking of the bitwise mask 165, differ from their respective bits in the expected bit pattern 121 to a division logic circuit 180.

The bitwise mask 165 further passes the masked error bit pattern 131 onto a compared bit counter 155. The compared bit counter 155 counts the total number of bits in the masked error bit pattern 131 and transfers that count to the division logic circuit 180.

Representative embodiments for parallel busses can count errors using a variety of techniques which include, but are not limited to, (1) the use of one error bit counter per bit whether or not the bits are masked, (2) the use of one error bit counter per bus which counts all error bits on each state with the counter on each state potentially incremented by 0 up to N where N is the bus width whether or not the bits are masked, and (3) the use of one error bit counter that counts one time per state if one or more bits in the bus were found to be in error whether or not the bits are masked.

The compared bit counter 155 counts the total number of bits in the masked error bit pattern 131 and transfers that count to the division logic circuit 180. The division logic circuit 180 divides the total number of error bits counted by the error bit counter 175 by the total number of bits counted by the compared bit counter 155 to obtain the bit error rate which is available at the division logic circuit output 186. A bit error rate calculator 185, also referred to herein as a calculator 185 and as a calculator circuit 185, comprises the compared bit counter 155, the error bit counter 175, and the division logic circuit 180.

In various embodiments, various masks can be used to restrict the bits being compared. As an example, if in the case of a parallel bus a design engineer has a known problem with bit line 3, he may prefer to run a bit error rate test masking out the bits on bit line 3 so that he can look for problems on other bit lines. In other cases, he may prefer not to mask at all.

For half-loopback test applications, the sequencer 110 receives the input datastream and parses it, in real time, looking for a start of data sentinel. This sentinel can be as simple as a single bit pattern or it could be complex pattern sequence spanning multiple samples. In any case there is typically a unique sample or sequence of samples in the data stream received from the device under test 105 that the sequencer 110 is programmed to detect that tells the sequencer 110 that the test has begun. For such tests, the sequencer 110 is programmed as to the test pattern which it expects to receive from the device under test. The term start of data pattern will be used herein to comprise the sentinel in the test start bit pattern, or any other appropriate means, that may be used to inform the sequencer that the first bits of the data to be used for comparison in calculating a bit error rate are being received.

Other features which, for example, could be a reduction OR circuit 190 could be added to the system 100. With this feature, the reduction OR circuit 190 receives the masked error bit pattern 131 from the bitwise mask 165 with the reduction OR circuit 190 outputting a signal which indicates either that there were no errors detected or that there was at least one error detected. In representative embodiments, the reduction OR circuit 190 generates a flag which could be staved to logic analyzer trace memory along with, for example, the received bit pattern 126 or the returned bit pattern 127 to identify which bus samples contained error bits.

FIG. 1B is a block diagram of another system 100 for measuring the bit error rate of the device under test (DUT) 105 as described in various representative embodiments. In FIG. 1B, the sequencer 110 in the test instrument 115 obtains at least part of the transmitted bit pattern 122 from the pattern memory 160 and transmits the transmitted bit pattern 122 to the device under test 105 via the Input/Output (I/O) circuit 145. The test instrument 115 via I/O circuit 145 receives back the received bit pattern 126 from the device under test 105 which, in response to the transmitted bit pattern 122 comprises the return bit pattern 127 (see again FIG. 2C and related discussion). After removing any invalid bit patterns 128 (see again first invalid bit pattern 128A and second invalid bit pattern 128B in FIG. 2C with related discussion) and any beginning and end of test indicators from the return bit pattern 127, the sequencer 110 passes the resultant bit pattern as the response bit pattern 129 (see again first-part response bit pattern 129A, second-part response bit pattern 129B, and third-part response bit pattern 129C in FIGS. 2C-2D with related discussion) to the digital comparator 150.

The digital comparator 150 obtains the expected bit pattern 121 from a pattern memory 160 and compares the response bit pattern 129 to the expected bit pattern 121. The digital comparator 150 identifies those bits in the response bit pattern 129 that differ from their respective bits in the expected bit pattern 121 with the result of that comparison being error bit pattern 130. The digital comparator 150 then passes the resultant error bit pattern 130 to error bit counter 175 which from the identification of error bits in the error bit pattern 130 counts those bits in the response bit pattern 129 that differ from their respective bits in the expected bit pattern 121. The error bit counter 175 transfers the count of those bits in the response bit pattern 129 that differ from their respective bits in the expected bit pattern 121 to the division logic circuit 180.

The digital comparator 150 further passes the error bit pattern 130 onto a compared bit counter 155. The compared bit counter 155 counts the total number of bits in the error bit pattern 130 and transfers that count to the bit error rate calculator 185. The division logic circuit 180 divides the total number of error bits counted by the error bit counter 175 by the total number of bits counted by the compared bit counter 155 to obtain the bit error rate which is available at the division logic circuit output 186. Here also, the bit error rate calculator 185, comprises the compared bit counter 155, the error bit counter 175, and the division logic circuit 180.

Again as with FIG. 1A other features which, for example, could be a reduction OR circuit 190 could be added to the system 100. With this feature, the reduction OR circuit 190 receives the error bit pattern 130 from digital comparator 150 with the reduction OR circuit 190 outputting a signal which indicates either that there were no errors detected or that there was at least one error detected.

The test instrument 115 could be, for example, a logic analyzer. Clocking signals necessary for operation of the system 100 could be obtained from the test instrument 115, the device under test 105, or another appropriate source. The digital comparator 150 could be an exclusive OR circuit which combines the response bit pattern 129 with the expected bit pattern 121 with a resultant “0” when a particular bit in the response bit pattern 129 is identical with its corresponding bit in the expected bit pattern 121 and with a resultant “1” otherwise. Bit streams may be transmitted and received in a variety of physical and logical formats including, but not limited to, serial buses and parallel buses. Transmission/reception can occur via wireless as well as hard wired connections. In addition, information may be transmitted and received as digital signals in data packets.

FIG. 2A is a block diagram of a representative bit pattern as used in the measurement of bit error rate in the system 100 of FIG. 1A-1B. In the representative example of FIG. 2A, the expected bit pattern 121 conceptually and for illustrative purposes comprises a first-part expected bit pattern 121A, a second-part expected bit pattern 121B, and a third-part expected bit pattern 121C. The first-part expected bit pattern 121A, the second-part expected bit pattern 121B, and the third-part expected bit pattern 121C will be discussed in more detail with respect to FIG. 2D.

FIG. 2B is a block diagram of another representative bit pattern as used in the measurement of bit error rate in the system 100 of FIG. 1A-1B. In the representative example of FIG. 2B, the transmitted bit pattern 122 comprises a test start bit pattern 123, also referred to herein as a start of data pattern 123, a test bit pattern 125, and a test end bit pattern 124. The test bit pattern 125 conceptually and for illustrative purposes comprises a first-part test bit pattern 125A, a second-part test bit pattern 125B, and a third-part test bit pattern 125C. The first-part test bit pattern 125A, second-part test bit pattern 125B, and third-part test bit pattern 125C correspond to the first-part expected bit pattern 121A, second-part expected bit pattern 121B, and third-part expected bit pattern 121C. For devices under test 105 which modify test bit patterns 125 prior to returning them to the test instrument 115, the expected bit pattern 121 will differ from the test bit pattern 125 accordingly. For devices under test 105 which do no modify test bit patterns 125 prior to returning them to the test instrument 115, the expected bit pattern 121 will be identical to the test bit pattern 125. For the present example then, the first-part test bit pattern 125A is the same as the first-part expected bit pattern 121A, the second-part test bit pattern 125B is the same as the second-part expected bit pattern 121B, and the third-part test bit pattern 125C is the same as the third-part expected bit pattern 121C.

FIG. 2C is a block diagram of still another representative bit pattern as used in the measurement of bit error rate in the system 100 of FIG. 1A-1B. In the representative example of FIG. 2C, the received bit pattern 126 comprises a leading bit stream 132, the return bit pattern 127, and a trailing bit stream 133. The leading bit stream 132 represents any bits that are received from the device under test 105 prior to test initiation, i.e., prior to receipt of the test start bit pattern 123 by the sequencer 110. The trailing bit stream 133 represents any bits that are received from the device under test 105 after completion of the bit error rate test, i.e., prior to receipt of the test end bit pattern 124 by the sequencer 110. The return bit pattern 127 comprises the test start bit pattern 123, a first-part response bit pattern 129A, the first invalid bit pattern 128A, a second-part response bit pattern 129B, the second invalid bit pattern 128B, a third-part response bit pattern 129C, and the test end bit pattern 124. First and second invalid bit patterns 128A,128B represent a variety of bit patterns that may be inserted into the transmitted or returned bit streams which the sequencer 110 has been programmed to ignore as these bit patterns are not a part of the data for which a comparison is to be performed. These invalid bit patterns 128A,128B could be, for example, idle states that have been inserted in order to keep the link open, dummy patterns inserted to allow for skips and/or insertions of bits and symbols, or the like.

FIG. 2D is a block diagram of yet other representative bit patterns as used in the measurement of bit error rate in the system 100 of FIG. 1A-1B. In the representative example of FIG. 2C and for illustrative purposes, the first-part expected bit pattern 121A, the second-part expected bit pattern 121B, and the third-part expected bit pattern 121C, of the expected bit pattern 121 of FIG. 2A are reproduced just above the first-part response bit pattern 129A, the second-part response bit pattern 129B, and the third-part response bit pattern 129C of the response bit pattern 129. The first-part expected bit pattern 121A, the second-part expected bit pattern 121B, and the third-part expected bit pattern 121C, of the expected bit pattern 121 differ from respectively the first-part response bit pattern 129A, the second-part response bit pattern 129B, and the third-part response bit pattern 129C of the response bit pattern 129 only in those bits in which an error has occurred. As previously indicated, the response bit pattern 129 is compared to the expected bit pattern 121 by the digital comparator circuit 150 of FIGS. 1A-1B.

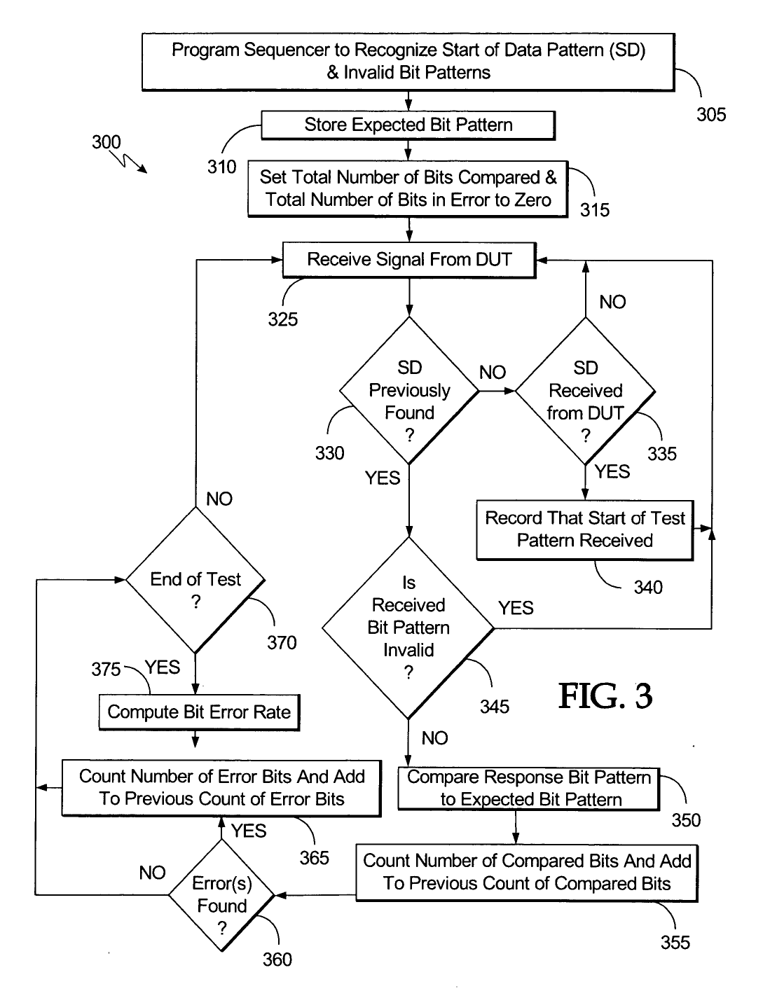

FIG. 3 is a flow chart of a method 300 for measuring the bit error rate of the device under test 105 as described in various representative embodiments. The method of FIG. 3 could be implemented, for example, in half-loopback tests. In block 305, the sequencer 110 is programmed to recognize the start of data pattern 123 and any known invalid bit patterns 128. Again, these invalid bit patterns 128 are dependent upon the particular protocol of the device under test 105. Note that the device under test 105 can be a communication link, a fixed device, or any combination. Block 305 then transfers control to block 310.

In block 310, the expected bit pattern 121 is stored in the pattern memory 160. Block 310 then transfers control to block 315.

In block 315, the total number of bits compared and the total number of bits in error are initialized to zero. Block 315 then transfers control to block 325.

In block 325, the test instrument 115 receives a bit or bit pattern in the received bit pattern 126 from the device under test 105. A representative example of the received bit pattern 126 is as shown in FIG. 2C. Typically, however, the test end bit pattern 124 would not be transmitted by the device under test 105. In such case, the test instrument 115 knows the number of bits in the expected bit pattern 121 and can terminate the test following receipt of that number of valid bits. Block 325 then transfers control to block 330.

In block 330, when the start of data pattern (SD) 123 was previously found in the received bit pattern 126, block 330 transfers control to block 345. Otherwise, block 330 transfers control to block 335.

In block 335, when the start of data pattern 123 is received by the test instrument 115, block 335 transfers control to block 340. Otherwise, block 335 transfers control to block 325.

In block 340, the fact that the start of data pattern 123 has been received is recorded. Block 340 then transfers control to block 325.

In block 345, when the bit or bit pattern of the received bit pattern 126 is one of the programmed invalid bit patterns 128 (first invalid bit pattern 128A or second invalid bit pattern 128B of FIG. 2C), block 345 transfers control to block 325. Note that for the half-loopback test the first-part response bit pattern 129A, second-part response bit pattern 129B, and third-part response bit pattern 129C in FIG. 2C are patterns generated by the device under test 105, and are not in response to patterns generated by the test instrument 115 as would be the case in full-loopback tests. Otherwise, block 345 transfers control to block 350.

In block 350, the part of the received bit pattern 129 remaining after removal of the invalid bit patterns 128 from the data stream is compared to the expected bit pattern 121. Such comparison could be performed, for example, by the digital comparator 150 of FIGS. 1A-1B. Block 350 then transfers control to block 355.

In block 355, the number of bits in the bit or bit pattern of the received bit pattern 126 is added to any previous count of the number of compared bits. Block 355 then transfers control to block 360.

In block 360, when an error is found in the compared bit pattern, block 360 transfers control to block 365. Otherwise, block 360 transfers control to block 370.

In block 365, the number of error bits in the compared bit pattern is added to any previous count of the number of error bits. Block 365 then transfers control to block 370.

In block 370, when the end of the test occurs, which could be, for example, indicated by the number of compared bits counted in block 355 reaching the known number of bits in the expected bit pattern 121, block 370 transfers control to block 375. Otherwise, block 370 transfers control to block 325.

In block 375, the bit error rate is computed. The bit error rate computation could be, for example, performed by the bit error rate calculator 185 as shown in FIGS. 1A-1B by dividing the number of bits in error by the number of compared bits. Block 375 then terminates the process.

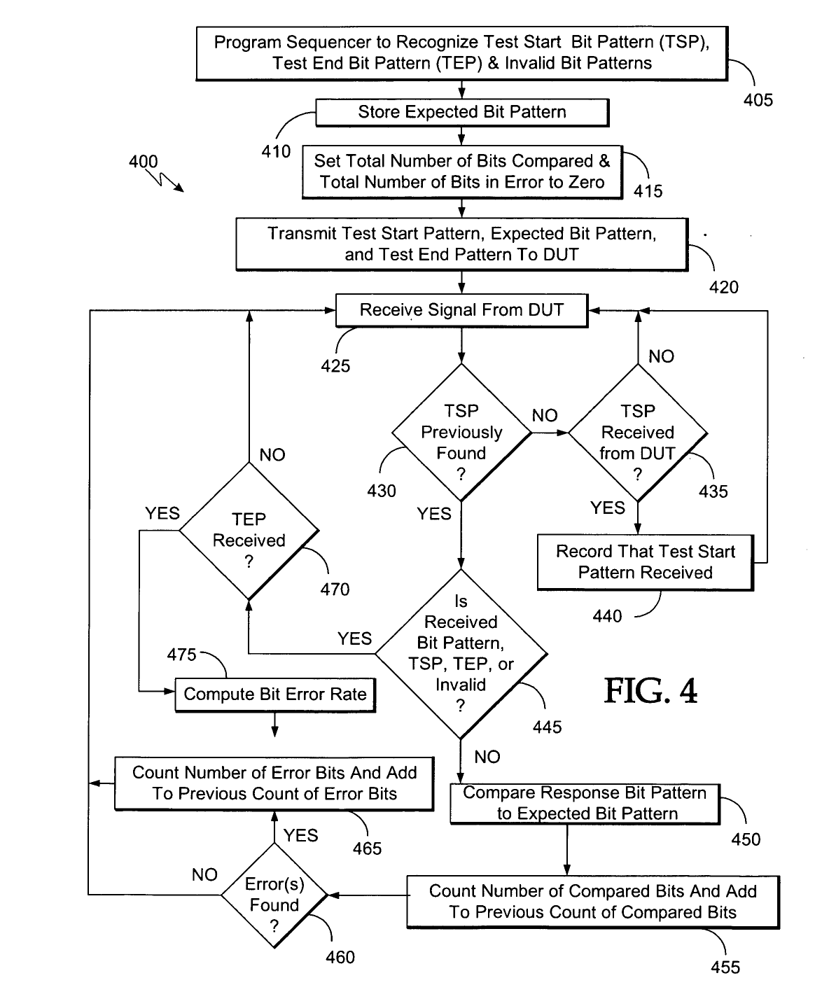

FIG. 4 is a flow chart of another method 400 for measuring the bit error rate of the device under test 105 as described in various representative embodiments. In block 405, the sequencer 110 is programmed to recognize the test start bit pattern 123, test end bit pattern 124, and any known invalid bit patterns 128. Again, these invalid bit patterns 128 are dependent upon the particular protocol of the device under test 105. Note that the device under test 105 can be a communication link, a fixed device, or any combination. Block 405 then transfers control to block 410.

In block 410, the expected bit pattern 121 is stored in the pattern memory 160. Block 410 then transfers control to block 415.

In block 415, the total number of bits compared and the total number of bits in error are initialized to zero. Block 415 then transfers control to block 420.

In block 420, the transmitted bit pattern 122 is transmitted to the device under test 105. Block 420 then transfers control to block 425.

In block 425, the test instrument 115 receives a bit or bit pattern in the received bit pattern 126 from the device under test 105. A representative example of the received bit pattern 126 is as shown in FIG. 2C. Block 425 then transfers control to block 430.

In block 430, when the test start bit pattern 123 was previously found in the received bit pattern 126, block 430 transfers control to block 445. Otherwise, block 430 transfers control to block 435.

In block 435, when the test start bit pattern 123 is received by the test instrument 115, block 435 transfers control to block 440. Otherwise, block 435 transfers control to block 425.

In block 440, the fact that the test start bit pattern 123 has been received is recorded. Block 440 then transfers control to block 425.

In block 445, when the bit or bit pattern of the received bit pattern 126 is one of the programmed invalid bit patterns 128 (first invalid bit pattern 128A or second invalid bit pattern 128B of FIG. 2C), block 445 transfers control to block 470. Otherwise, block 445 transfers control to block 450.

In block 450, the response bit pattern 129 is compared to the expected bit pattern 121. Such comparison could be performed, for example, by the digital comparator 150 of FIGS. 1A-1B. Block 450 then transfers control to block 455.

In block 455, the number of bits in the bit or bit pattern of the received bit pattern 126 is added to any previous count of the number of compared bits. Block 455 then transfers control to block 460.

In block 460, when an error is found in the compared bit pattern, block 460 transfers control to block 465. Otherwise, block 460 transfers control to block 425.

In block 465, the number of error bits in the compared bit pattern is added to any previous count of the number of error bits. Block 465 then transfers control to block 425.

In block 470, when the test end bit pattern 470 is received, block 470 transfers control to block 475. Otherwise, block 470 transfers control to block 425.

In block 475, the bit error rate is computed. The bit error rate computation could be, for example, performed by the bit error rate calculator 185 as shown in FIGS. 1A-1B by dividing the number of bits in error by the number of compared bits. Block 475 then terminates the process.

As is the case, in many data-processing products, the components describe above may be implemented as a combination of hardware and software components. Moreover, the functionality require for using the representative embodiments described herein may be embodied in computer-readable media (such as 3.5 inch diskettes or other floppy disks, conventional hard disks, DVD's, CD-ROM's, Flash ROM's, nonvolatile ROM, and RAM) to be used in programming an information-processing apparatus (e.g., a personal computer or test instrument).

The term “program storage medium” is broadly defined herein to include any kind of computer memory such as, but not limited to, floppy disks, conventional hard disks, DVD's, CD-ROM's, Flash ROM's, nonvolatile ROM, and RAM.

In the preferred embodiments described herein, novel techniques for the measurement of bit error rates in digital electronic systems are disclosed. The present solutions provide the ability to obtain an accurate representation of the bit error rate for those systems in which the pattern is dynamic as well as static. These techniques provide ways to remove various patterns which are protocol dependent and which have been inserted into the returned data stream from consideration in the computation of the bit error rate. The present techniques overcome shortcomings of prior solutions so that falsely high bit error rates will not be reported. The is user is not forced to employ a static pattern mode for the device under test in order to obtain a reasonable measure of the bit error rate

The representative embodiments, which have been described in detail herein, have been presented by way of example and not by way of limitation. It will be understood by those skilled in the art that various changes may be made in the form and details of the described embodiments resulting in equivalent embodiments that remain within the scope of the appended claims.

1. A method, comprising:
programming a sequencer circuit to recognize at least one predefined invalid bit pattern;
storing an expected bit pattern;
receiving a bit pattern from the device; and
after a start of data pattern is received by the sequencer and while the sequencer circuit recognizes the received bit pattern as other than invalid,
comparing the received bit pattern against the expected bit pattern;
computing a bit error rate based on the number of compared bits and the number of error bits, wherein error bits are bit pattern bits that differ from corresponding bits in the expected bit pattern.

2. The method as recited in claim 1, further comprising:
programming the sequencer circuit to recognize a test start bit pattern and a test end bit pattern, wherein start of data pattern comprises the test start bit pattern;
transmitting a transmitted bit pattern to the device,
wherein the transmitted bit pattern comprises, the test start bit pattern, a test bit pattern, and the test end bit pattern; and
in response to the transmitted bit pattern, receiving a return bit pattern from the device as a part of the received bit pattern,
wherein the comparing step occurs after test start bit pattern and before test end bit pattern are detected in the return bit pattern and
wherein the comparing step comprises comparing the return bit pattern against the expected bit pattern.

3. The method as recited in claim 2, wherein the expected bit pattern is identical to the test bit pattern.

4. The method as recited in claim 2, wherein the expected bit pattern differs from the test bit pattern.

5. The method as recited in claim 1, wherein the step computing the bit error rate further comprises:
counting number of compared bits;
counting number of error bits; and
dividing the number of error bits by the number of compared bits,
wherein the result of the dividing step is the bit error rate.

6. The method as recited in claim 5, wherein prior to the step computing the bit error rate, the result of the comparing step is masked to remove preselected bit locations from the count of number of compared bits and from the count of number of error bits.

7. The method as recited in claim 1, wherein the sequencer circuit is a component of a logic analyzer.

8. A computer readable memory device embodying a computer program of instructions executable by the computer, the instructions comprising:
programming a sequencer circuit to recognize at least one predefined invalid bit pattern;
storing an expected bit pattern;
receiving a bit pattern from the device; and
after a start of data pattern is received by the sequencer and while the sequencer circuit recognizes the received bit pattern as other than invalid,
comparing the received bit pattern against the expected bit pattern;
computing a bit error rate based on the number of compared bits and the number of error bits, wherein error bits are bit pattern bits that differ from corresponding bits in the expected bit pattern.

9. The computer readable memory device as recited in claim 8, the instructions further comprising:
programming the sequencer circuit to recognize a test start bit pattern and a test end bit pattern, wherein start of data pattern comprises the test start bit pattern;
transmitting a transmitted bit pattern to the device,
wherein the transmitted bit pattern comprises, the test start bit pattern, a test bit pattern, and the test end bit pattern; and
in response to the transmitted bit pattern, receiving a return bit pattern from the device as a part of the received bit pattern,
wherein the comparing step occurs after test start bit pattern and before test end bit pattern are detected in the return bit pattern and
wherein the comparing step comprises comparing the return bit pattern against the expected bit pattern.

10. The computer readable memory device as recited in claim 9, wherein the expected bit pattern is identical to the test bit pattern.

11. The computer readable memory device as recited in claim 9, wherein the expected bit pattern differs from the test bit pattern.

12. The computer readable memory device as recited in claim 8, wherein the step computing the bit error rate further comprises:
counting number of compared bits;
counting number of error bits; and
dividing the number of error bits by the number of compared bits,
wherein the result of the dividing step is the bit error rate.

13. The computer readable memory device as recited in claim 12, wherein prior to the step computing the bit error rate, the result of the comparing step is masked to remove preselected bit locations from the count of number of compared bits and from the count of number of error bits.

14. The computer readable memory device as recited in claim 8, wherein the sequencer circuit is a component of a logic analyzer.

15. A test instrument for measuring a bit error rate of a device, comprising:
a sequencer circuit capable of receiving a bit pattern from the device and modifying the received bit pattern by removing bit patterns previously identified to the sequencer as invalid;
a memory capable of storing an expected bit pattern;
a digital comparator having a first input, a second input, and an output,
wherein the first input is connected to an output of the sequencer circuit and is capable of receiving bit pattern as modified by the sequencer,
wherein the second input is connected to the memory and is capable of receiving the stored expected bit pattern, and
wherein the output is capable of receiving result of a comparison of bit pattern applied to the first input with bit pattern applied to the second input; and
a bit error rate calculator with input connected to the output of the digital comparator, wherein the bit error rate calculator has capability of calculating a bit error rate.

16. The test instrument as recited in claim 15, wherein the bit rate calculator comprises:
a compared bit counter connected to the digital comparator circuit and having capability of counting the number of bits in the bit patterns compared by the digital comparator;
an error bit counter connected to the digital comparator circuit and having capability of counting the number of error bits in the bit pattern compared by the digital comparator; and
a division logic circuit having inputs separately connected to outputs of the compared bit counter and the error bit counter, having capability of receiving the number counted by the error bit counter and the number counted by the compared bit counter, and having capability of dividing the number received from the error bit counter by the number received from the compared bit counter.

17. The test instrument as recited in claim 15, further comprising:
a bit mask connected to the output of the digital comparator capable of masking predefined bit locations, wherein input of the bit error rate calculator is connected to output of the bit mask and disconnected from the digital comparator circuit.

18. The test instrument as recited in claim 15, wherein the sequencer circuit is a component of a logic analyzer.
